(19) United States
(12) Patent Application Publication
(10) Pub. No.: US 2026/0229303 A1
(43) Pub. Date: Aug. 6, 2026

(54) MEMORY DEVICE AND OPERATING METHOD OF THE SAME

(71) Applicant: SK hynix Inc., Icheon-si (KR)

(72) Inventors: Ung Hee Park, Icheon-si (KR); Gap Sok Do, Icheon-si (KR)

(21) Appl. No.: 19/283,841

(22) Filed: Jul. 29, 2025

(30) Foreign Application Priority Data
Jan. 31, 2025 (KR) 10-2025-0012317

(51) Int. Cl. G11C 29/12; G11C 29/44

(52) U.S. Cl. CPC G11C 29/12005; G11C 29/44; G11C 2029/1202; G11C 2029/1204

(57) ABSTRACT

A method for operating a memory device includes receiving a first write command; performing a first pre-selection operation to determine whether a first memory cell is capable of being turned on; performing a second pre-selection operation to determine whether the first memory cell is capable of being turned on if the first pre-selection operation did not cause the first memory cell to be turned on; and determining the first memory cell to be a failed cell if the second pre-selection operation did not cause the first memory cell to be turned on.

### CROSS-REFERENCE TO RELATED APPLICATION

This application claims priority under 35 U.S.C. § 119(a) to Korean Patent Application No. 10-2025-0012317, filed in the Korean Intellectual Property Office on Jan. 31, 2025, the entire contents of which are incorporated herein by reference.

### BACKGROUND

### 1. Technical Field

Embodiments relate to an integrated circuit technology and, more particularly, to a memory device and an operating method of the same.

### 2. Related Art

Recently, as an electronic device is reduced in size, has lower power consumption and higher performance, and is diversified, memory capable of storing information is required for various electronic devices, such as computers and portable communication devices.

Memory that is being researched also includes memory capable of storing data by using a characteristic in which the memory switches between different resistance states depending on a voltage or current applied thereto. Such memory includes resistive random access memory (RRAM), phase change random access memory (PRAM), ferroelectric random access memory (FRAM), magnetic random access memory (MRAM), an E-fuse, and selector only memory (SOM).

### SUMMARY

In an embodiment, an operating method of a memory device may include receiving a first write command, performing a first pre-selection operation of determining whether a first memory cell has been turned on, checking that the first memory cell has not been turned on based on the results of the first pre-selection operation and performing a second pre-selection operation, and checking that the first memory cell has not been turned on based on the results of the second pre-selection operation and determining the first memory cell to be a failed cell.

In an embodiment, a memory device may include a cell array including at least one memory cell that is electrically connected between a bit line that is electrically connected to a global bit line and a word line that is electrically connected to a global word line, a control circuit configured to control at least one of a first pre-selection operation, a second pre-selection operation, and a write operation to be performed when receiving a write command, a voltage supply circuit configured to provide a first pre-selection operation voltage to the global bit line and configured to provide a second pre-selection operation voltage to the global word line after the start of the first pre-selection operation, and a sense amplifier configured to provide the control circuit with information indicating whether the memory cell has been turned on as results of the first and second pre-selection operations.

In an embodiment, a method for operating a non-volatile memory device includes receiving a write command for a memory cell. A first pre-selection operation is performed on the memory cell. A second pre-selection operation is performed on the memory cell if the memory cell does not exhibit a conductive state in response to the first pre-selection operation. The write operation is performed on the memory cell if the memory cell exhibits a conductive state in response to at least one of the first or second pre-selection operations. The memory cell is classified as a failed cell if the memory cell does not exhibit a conductive state in response to the first and second pre-selection operations.

### BRIEF DESCRIPTION OF THE DRAWINGS

FIGS. 1 and 2 are diagrams for describing a write operation for a memory cell according to an embodiment of the present disclosure.

FIGS. 3 and 4 are diagrams for describing a write operation of a memory device according to an embodiment of the present disclosure.

FIG. 5 is a flowchart for describing an operation of the memory device according to an embodiment of the present disclosure.

FIGS. 6 to 8 are diagrams for describing an operation of the memory device according to an embodiment of the present disclosure.

FIG. 9 is a diagram for describing components of the memory device according to an embodiment of the present disclosure.

### DETAILED DESCRIPTION

Hereinafter, embodiments according to the technical spirit of the present disclosure are described with reference to the accompanying drawings.

Embodiments of the present disclosure relate to techniques for operating a non-volatile memory device to improve write reliability by mitigating the effects of sneak path currents. In an embodiment, a method includes performing a first pre-selection operation (e.g., by applying a first voltage across the cell) on a memory cell after receiving a write command. If the memory cell does not exhibit a conductive state (e.g., is not turned on), a second pre-selection operation (e.g., by applying a second voltage across the cell) is performed on the memory cell. A write operation is performed if the memory cell exhibits a conductive state in response to at least one of the first or the second pre-selection operation. The memory cell is classified as a failed cell if the memory cell remains non-conductive after the first and the second pre-selection operations.

Provided are a memory device capable of performing a write operation by determining a normal cell and an abnormal cell and an operating method of the same.

The data storage reliability of a memory cell can be improved.

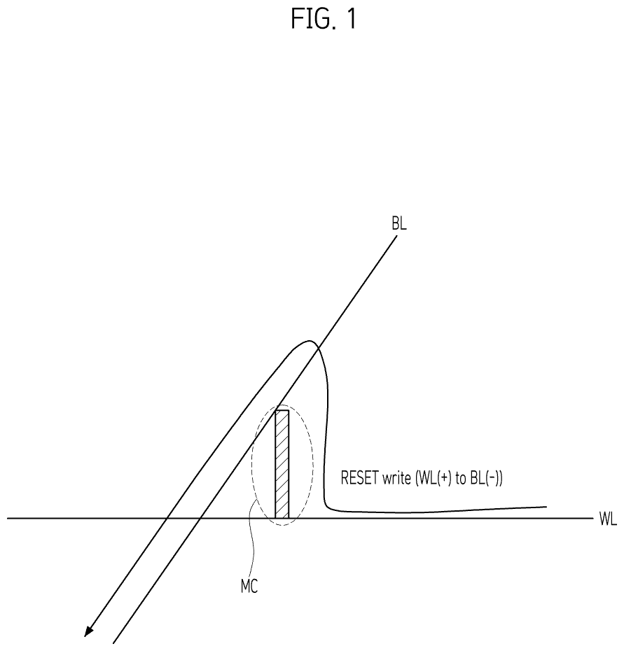

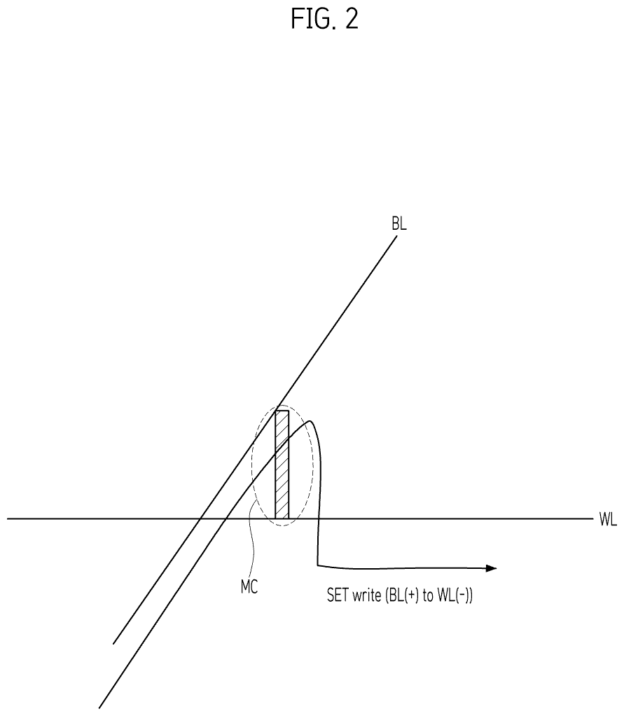

FIGS. 1 and 2 are diagrams for describing a write operation for a memory cell according to an embodiment of the present disclosure.

FIG. 1 may be a diagram for describing a reset (RESET) write operation of storing reset data in a memory cell MC. The threshold voltage of the memory cell MC may be changed depending on the direction of a current that penetrates the memory cell MC. For example, the threshold voltage of the memory cell MC may be changed into one of a first level and a second level depending on the direction of a current that penetrates the memory cell MC. The first level may be higher than the second level. In this case, when the threshold voltage of the memory cell MC is the first level, the state of the memory cell MC may be a reset state in which reset data have been stored in the memory cell MC. Furthermore, when the threshold voltage of the memory cell MC is the second level, the state of the memory cell MC may be a set state in which set data have been stored in the memory cell MC.

Referring to FIG. 1, the memory cell MC may be electrically coupled to a bit line BL and a word line WL. In this case, a reset write operation may be an operation of changing the state of the memory cell MC into the reset state by storing reset data in the memory cell MC. For example, the reset data may be stored in the memory cell MC by providing a first voltage to the word line WL and providing a second voltage to the bit line BL so that the memory cell MC is turned on and making a current flow from the word line WL to the bit line BL through the memory cell MC that has been turned on. In this case, the first voltage may be a voltage having a higher level than the second voltage. Furthermore, the first voltage may be a positive voltage (+), and the second voltage may be a negative voltage (−).

FIG. 2 may be a diagram for describing a set (SET) write operation of storing set data in the memory cell MC.

Referring to FIG. 2, the memory cell MC may be electrically coupled between the bit line BL and the word line WL. In this case, the set write operation may be an operation of changing the state of the memory cell MC into the reset state by storing set data in the memory cell MC. For example, the set data may be stored in the memory cell MC by providing a first voltage to the bit line BL and providing a second voltage to the word line WL so that the memory cell MC is turned on and making a current flow from the bit line BL to the word line WL through the memory cell MC that has been turned on. In this case, the first voltage may be a voltage having a higher level than the second voltage. Furthermore, the first voltage may be a positive voltage (+), and the second voltage may be a negative voltage (−).

In this case, when the threshold voltage of the memory cell MC is a first level higher than a second level, it may be said that the state of the memory cell MC has been changed into a state in which reset data have been stored in the memory cell MC, that is, a reset state. Furthermore, when the threshold voltage of the memory cell MC is the second level lower than the first level, it may be said that the state of the memory cell MC has been changed into a state in which set data have been stored in the memory cell MC, that is, a set state.

That is, the level of the threshold voltage of the memory cell MC in which the reset data have been stored may be higher than the level of the threshold voltage of the memory cell MC in which the set data have been stored.

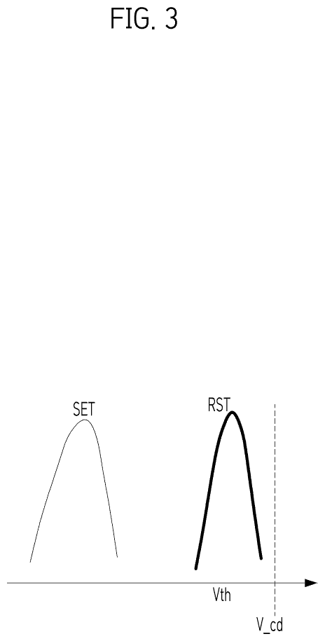

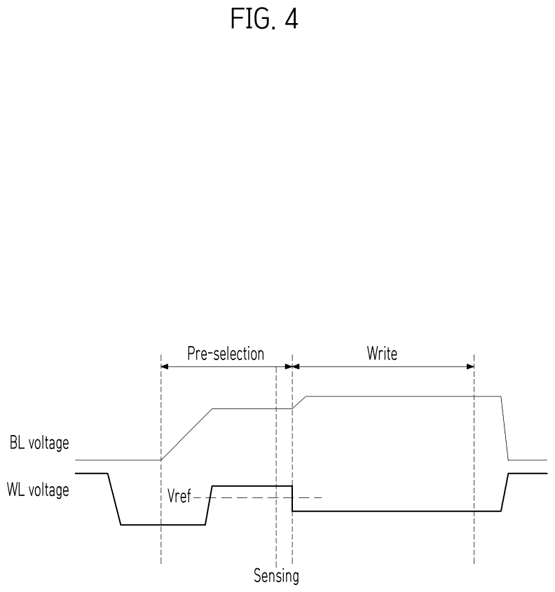

FIGS. 3 and 4 are diagrams for describing a write operation of a memory device according to an embodiment of the present disclosure. In this case, FIGS. 3 and 4 may be diagrams for describing the write operation of the memory device that performs the write operation after determining whether the memory cell MC having the characteristics described with reference to FIGS. 1 and 2 is a normal cell or an abnormal cell.

FIG. 3 may illustrate a distribution (RST) of the threshold voltages of the memory cells MC, which has been formed by the reset write operation of FIG. 1, and a distribution (SET) of the threshold voltages of the memory cells MC, which has been formed by the set write operation of FIG. 2.

FIG. 4 may be a diagram for describing a pre-selection (Pre-selection) operation of determining whether a memory cell MC is normal before performing a reset write (Write) operation or a set write (Write) operation on the memory cell MC.

Referring to FIGS. 3 and 4, a memory device according to an embodiment of the present disclosure may perform the pre-selection operation and then perform a write operation (e.g., a reset (RESET) write or set (SET) write operation). In this case, the write operation described with reference to FIG. 4 may be a set (SET) write operation.

The pre-selection operation may be an operation of providing a cell determination signal to the memory cell to assess whether it is operating normally prior to a write operation. The cell determination signal may be a voltage or a current. In an embodiment, the cell determination signal is a cell determination voltage V_cd applied across the memory cell MC (e.g., first and second ends of the memory cell). The pre-selection operation includes determining whether the memory cell is has been turned on in response to the cell determination voltage V_cd. In an embodiment, the memory cell is turned on if it is in a conductive state. As used herein, a “conductive state” of a memory cell refers to a condition in which the memory cell allows current to flow between its terminals in response to an applied voltage or current, indicating a functional or non-defective memory cell.

At this time, when the memory cell MC is turned on, the memory device may determine the memory cell MC to be a normal memory cell. When the memory cell MC is not turned on, the memory device may determine the memory cell MC to be an abnormal memory cell. Furthermore, the cell determination voltage V_cd may have a higher level than the threshold voltage of the memory cell MC in the reset state RST, and may have a level lower than a voltage level between the voltage levels of the bit line BL and the word line WL after the start of a write operation. In the pre-selection operation of FIG. 4, a case in which the voltage level of the bit line BL is higher than the voltage level of the word line WL is described as an embodiment, but a pre-selection operation in which the voltage level of the bit line BL is lower than the voltage level of the word line may also be possible. That is, a pre-selection operation may be possible when a difference between the voltage levels of the bit line BL and the word line WL is the level of the cell determination voltage V_cd because the pre-selection operation is an operation of determining whether the memory cell MC has been turned on.

Accordingly, when the cell determination voltage V_cd is provided to the memory cell MC, the normal memory cell MC is turned on. The voltage level of the word line WL or the bit line BL may be changed due to the memory cell MC that has been turned on. For example, a current flows from the bit line BL to the word line WL through the memory cell MC that has been turned on. Accordingly, the memory cell MC may be determined to have been turned on when the voltage level of the word line WL becomes higher than the level of a reference voltage Vref by sensing the voltage level of the word line WL. Furthermore, when the voltage level of the word line WL is lower than the level of the reference voltage Vref, that is, when the voltage level of the word line WL is not changed, the memory cell MC may be determined to have been turned off.

As described above, the memory device according to an embodiment of the present disclosure may perform a write operation, after determining whether the memory cell MC to be written, that is, a target memory cell, is normal by performing a pre-selection operation before performing the write operation. When the memory cell MC is determined to be an abnormal memory cell based on the results of the pre-selection operation, the write (Write) operation might not be performed.

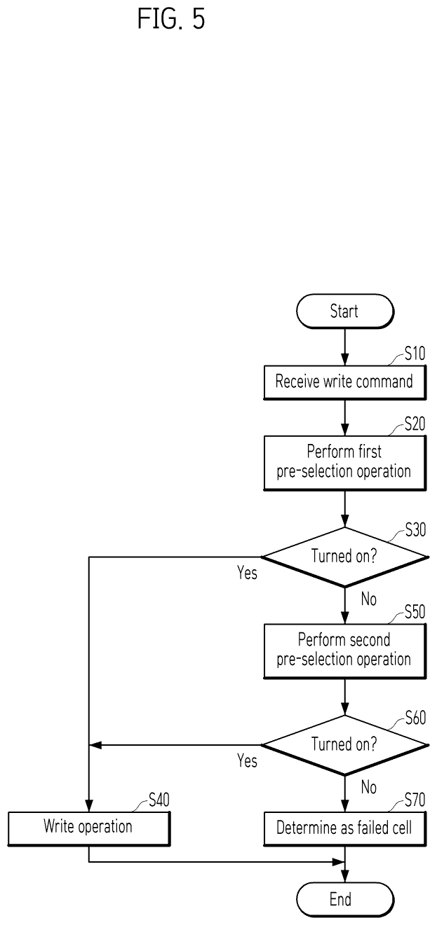

FIG. 5 is a flowchart for describing an operation of the memory device according to an embodiment of the present disclosure.

Referring to FIG. 5, the operating method of the memory device according to an embodiment of the present disclosure may include a write command reception process S10, a first pre-selection operation execution process S20, a first turn-on check process S30, a write operation execution process S40, a second pre-selection operation execution process S50, a second turn-on check process S60, and a failed cell determination process S70.

The write command reception process S10 may include a process of receiving, by the memory device, a write command. In this case, when the memory device receives the write command, the first pre-selection operation execution process S20 may be performed.

The first pre-selection operation execution process S20 may include a process of providing the cell determination voltage V_cd to both ends of the memory cell MC. In this case, in the first pre-selection operation execution process S20, when the memory cell MC is turned on, a current may flow in a first direction. For example, the first direction may be a direction in which a current flows from the bit line BL to the word line WL through the memory cell MC. The first direction may be a direction in which a current flows from the word line WL to the bit line BL through the memory cell MC.

The first turn-on check process S30 is a process of checking the results of the first pre-selection operation, and may be a process of checking whether the memory cell MC has been turned on. For example, the first turn-on check process S30 may be a process of detecting a change in the voltage level of the bit line BL or the word line WL due to the memory cell MC that has been turned on. This is described more specifically as an example. The first turn-on check process S30 may be a process of determining that the memory cell MC has been turned on when the voltage level of the bit line BL or the word line WL becomes higher or lower than the level of the reference voltage Vref. The first turn-on check process S30 may be a process of determining that the memory cell MC has not been turned on when the voltage level of the bit line BL or the word line WL is not higher or lower than the level of the reference voltage Vref, that is, when the voltage level of the bit line BL or the word line WL is not changed. If a current flows from the bit line BL to the word line WL due to the memory cell MC that has been turned on, the voltage level of the word line WL may become higher than the level of the reference voltage Vref. Furthermore, if a current flows from the bit line BL to the word line WL due to the memory cell MC that has been turned on, the voltage level of the bit line BL may become lower than the level of the reference voltage Vref.

When it is checked that the memory cell MC has been turned on (Yes) in the first turn-on check process S30, the write operation execution process S40 may be performed.

When it is checked that the memory cell MC has not been turned on (No) in the first turn-on check process S30, the second pre-selection operation execution process S50 may be performed.

The write operation execution process S40 may include an operation of changing the state of the memory cell MC into the reset state or the set state. In this case, the write operation execution process S40 may include a process of providing the memory cell MC with a voltage having a higher level than the cell determination voltage V_cd by applying a voltage to each of both ends of the memory cell MC, that is, the bit line BL and the word line WL.

The second pre-selection operation execution process S50 may include a process of providing the cell determination voltage V_cd to both ends of the memory cell MC. In this case, in the second pre-selection operation execution process S50, when the memory cell MC is turned on, a current may flow in a second direction. For example, the second direction may be a direction opposite to the direction in which a current flows through the memory cell MC that has been turned on in the first pre-selection operation execution process S20. For example, if the direction in which the current flows through the memory cell MC that has been turned on in the first pre-selection operation execution process S20 is a direction in which the current flows from the bit line BL to the word line WL, a direction in which a current flows through the memory cell MC that has been turned on in the second pre-selection operation execution process S50 may be a direction in which a current flows from the word line WL to the bit line BL. That is, the second pre-selection operation execution process S50 may be a process of switching the voltages that have been provided to both ends of the memory cell MC, that is, the bit line BL and the word line WL, respectively, in the first pre-selection operation execution process S20. This is described more specifically. If a first voltage has been provided to the bit line BL and a second voltage has been provided to the word line WL in the first pre-selection operation execution process S20, the second voltage may be provided to the bit line BL and the first voltage may be provided to the word line WL in the second pre-selection operation execution process S50.

The second turn-on check process S60 is a process of checking the results of the second pre-selection operation, and may be a process of checking whether the memory cell MC has been turned on. For example, the second turn-on check process S60 may be a process of detecting a change in the voltage level of the bit line BL or the word line WL due to the memory cell MC that has been turned on. This is described more specifically as an example. The second turn-on check process S60 may be a process of determining that the memory cell MC has been turned on when the voltage level of the bit line BL or the word line WL becomes higher or lower than the level of the reference voltage Vref. The second turn-on check process S60 may be a process of determining that the memory cell MC has not been turned on when the voltage level of the bit line BL or the word line WL is not higher or lower than the level of the reference voltage Vref, that is, when the voltage level of the bit line BL or the word line WL is not changed.

When it is checked that the memory cell MC has been turned on (Yes) in the second turn-on check process S60, the write operation execution process S40 may be performed.

When it is checked that the memory cell MC has not been turned on (No) in the second turn-on check process S60, the failed cell determination process S70 may be performed.

The failed cell determination process S70 is a process of determining or classifying the memory cell MC to be a failed cell, and may further include a process of storing the address of the memory cell MC or transmitting the address of the memory cell MC to a controller that controls the memory device.

In this case, in the operating method of the memory device described with reference to FIG. 5, a write operation may be performed on the memory cell MC based on the results of the first pre-selection operation according to one write command. Furthermore, the second pre-selection operation may be performed based on the results of the first pre-selection operation according to another read command, and a write operation may be performed on the memory cell MC based on the results of the second pre-selection operation. The second pre-selection operation may be performed based on the results of the first pre-selection operation according to still another read command, and the memory cell MC may be determined to be a failed cell based on the results of the second pre-selection operation.

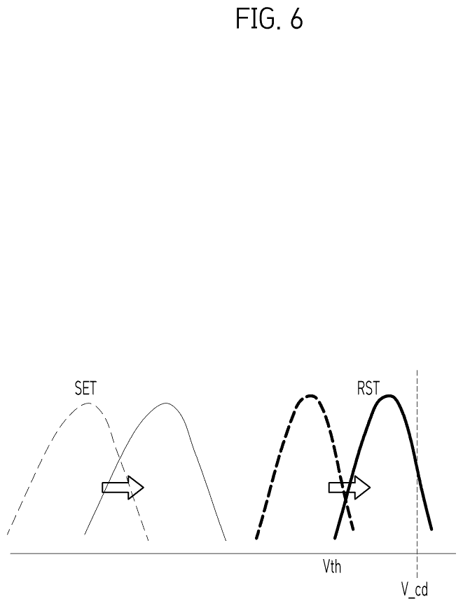

FIGS. 6 to 9 are diagrams for describing an operation of the memory device according to an embodiment of the present disclosure.

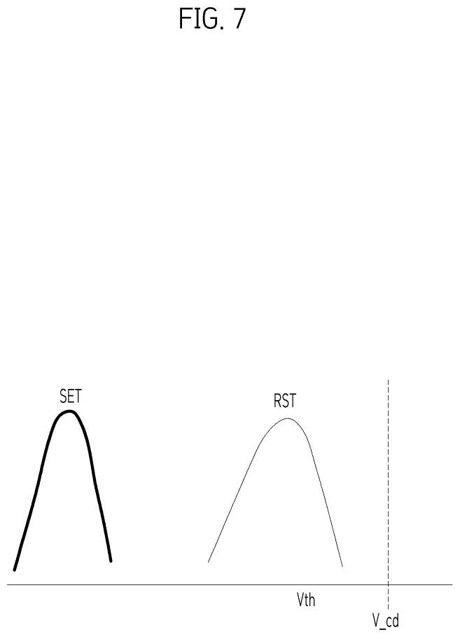

FIGS. 6 and 7 may be diagrams for describing an operation of preventing a normal memory cell from being determined to be a failed cell due to a sneak current after the start of a pre-selection operation. FIG. 6 may be a diagram for describing a first pre-selection operation. FIG. 7 may be a diagram for describing a second pre-selection operation.

In this case, the memory cell MC has a characteristic in which a current better flows through the memory cell MC, compared to a case in which a current flows through the memory cell MC in an opposite direction, when the current flows through the memory cell MC in the same direction as a direction in which the current flows through the memory cell MC after the start of a write operation. That is, when the memory cell MC is read, an operation of making a current flow in a direction opposite to a direction in a reset write operation, that is, a read operation, may be performed so that the current flows in the same direction as a direction in a set write operation. In this case, in the read operation of making the current flow in the same direction as the direction after the start of the set write operation, when the memory cell MC is turned on, the state of the memory cell MC may be determined to be the state in which the threshold voltage of the memory cell MC is low (the set state). When the memory cell MC is not turned on, the state of the memory cell MC may be determined to be the state in which the threshold voltage of the memory cell MC is high (the reset state). If a read operation is performed so that a current flows in the same direction as a reset direction when the memory cell MC is read, the state of the memory cell MC may be determined to be the state in which the threshold voltage of the memory cell MC is low when the memory cell is turned on, and may be determined to be the state in which the threshold voltage of the memory cell MC is high when the memory cell is not turned on. In this case, the state of the memory cell MC is checked on the basis of the read operation of making a current flow in the same direction as the direction after the start of the set write operation. After the start of the read operation of making a current flow in the same direction as the direction in the reset write operation, the state of the memory cell MC having a low threshold voltage may be the reset state, and the state of the memory cell MC having a high threshold voltage may be the set state.

Accordingly, a distribution of the threshold voltages of the memory cells after the start of the first pre-selection operation when the direction of a current that penetrates the memory cell is the first direction and a distribution of the threshold voltages of the memory cells after the start of the second pre-selection operation in a direction opposite to the first direction, that is, the second direction, may be switched as illustrated in FIGS. 6 and 7. The reset state RST in FIG. 6 may correspond to the set state SET in FIG. 7, and the set state SET in FIG. 6 may correspond to the reset state RST in FIG. 7.

As described above, the memory device according to an embodiment of the present disclosure may provide the cell determination voltage V_cd to the memory cell MC prior to a write operation, and may perform a pre-selection operation of determining whether the memory cell MC is normal by detecting the voltage level of a specific node that is connected to the bit line BL or the word line WL.

For example, a memory device that determines whether the memory cell MC has been turned on by detecting the voltage level of the word line WL is assumed.

The memory device may receive a write command.

The memory device may perform a first pre-selection operation prior to a write operation. In this case, the first pre-selection operation may be an operation of applying a higher voltage to the bit line BL than to the word line WL so that a current flows from the bit line BL to the word line WL through the memory cell MC that has been turned on, when the memory cell MC is turned on. In this case, a difference between the voltage levels of both ends of the memory cell MC, that is, the voltage levels of the bit line BL and the word line WL, may be a voltage level to the extent that the memory cell MC may be turned on. That is, after the start of the first pre-selection operation, a difference between the voltage levels of the bit line BL and the word line WL may correspond to the cell determination voltage V_cd. After the start of the first pre-selection operation, the amount of a sneak current may be increased as the number of memory cells having a low resistance state (e.g., the set state SET) is increased around a target memory cell on which a write operation is performed, that is, a memory cell selected after the start of the write operation. A voltage difference to the extent that a selected memory cell may be turned on needs to be provided to both ends of the selected memory cell after the start of the first pre-selection operation. However, if the amount of a sneak current is increased depending on the state of memory cells around the selected memory cell, a voltage difference to the extent that the selected memory cell may be turned on may not occur across the selected memory cell.

If the memory cell MC is determined to have been turned on in the first pre-selection operation, the write operation may be performed.

However, if the memory cell MC is determined to have not been turned on in the first pre-selection operation, a second pre-selection operation may be performed.

The second pre-selection operation may be an operation of performing a pre-selection operation so that a direction in which a current flows through the memory cell MC that has been turned on is opposite to a direction in which a current flows through the memory cell MC after the start of the first pre-selection operation. For example, if the first pre-selection operation is an operation of forming a current that flows from the bit line BL to the word line WL through the memory cell MC that has been turned on by applying a higher voltage to the bit line BL than to the word line WL, the second pre-selection operation may be an operation of forming a current that flows from the word line WL to the bit line BL through the memory cell MC that has been turned on by applying a higher voltage to the word line WL than to the bit line BL. Accordingly, if the memory cell MC is determined to have been turned off due to a sneak current in the first pre-selection operation, the memory cell MC may be determined to be turned on in the second pre-selection operation. The reason for this is that if memory cells in the low resistance state around the selected memory cell MC may increase the amount of a sneak current in the first pre-selection operation of applying a higher voltage to the bit line BL than to the word line WL, memory cells in a high resistance state around the selected memory cell MC may reduce the amount of the sneak current in the second pre-selection operation of applying a higher voltage to the word line WL than to the bit line BL. Memory cells have a characteristic (the low resistance state) in which a current well flows through the memory cells in the same direction as a direction after the start of a write operation and have a characteristic (the high resistance state) in which a current does not well flow through the memory cells in a direction opposite to a direction after the start of a write operation.

Therefore, whether the memory cell MC has been turned on may be determined in the second pre-selection operation without being affected by a sneak current compared to the first pre-selection operation.

If it is checked that the memory cell MC has been turned on in the second pre-selection operation, the write operation may be performed.

Accordingly, the memory device according to an embodiment of the present disclosure can prevent a normal memory cell from being erroneously determined to be an abnormal memory cell due to a sneak current by performing the second pre-selection operation based on the results of the first pre-selection operation.

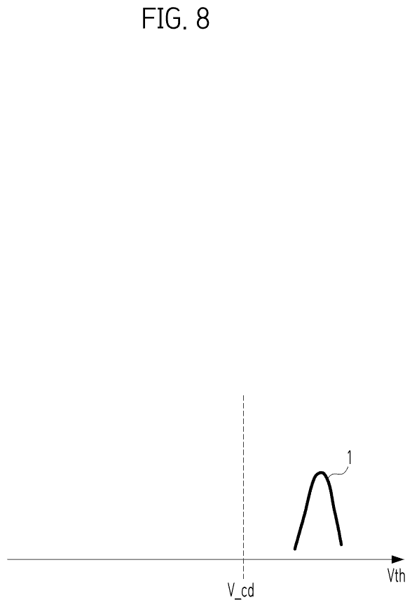

FIG. 8 may be a diagram for describing an operation of checking that a memory cell MC is a failed cell through first and second pre-selection operations.

As illustrated in FIG. 8, it is assumed that the memory cell MC has an abnormal distribution 1. In this case, the abnormal distribution 1 may mean a distribution of the threshold voltages of memory cells each having a higher level than the cell determination voltage V_cd.

The memory device may receive a write command.

The memory device may perform a first pre-selection operation prior to a write operation. In this case, in the first pre-selection operation, a current may flow from the bit line BL to the word line WL through the memory cell MC that has been turned on, when the memory cell MC is turned on.

As illustrated in FIG. 8, the abnormal distribution 1 is a distribution of the threshold voltages each having a higher level than the cell determination voltage V_cd. Accordingly, the memory cell MC having the abnormal distribution 1 may be determined to have been turned off after the start of the first pre-selection operation.

If the memory cell MC is determined to have been turned off in the first pre-selection operation, a second pre-selection operation may be performed.

The second pre-selection operation is opposite to the first pre-selection operation in voltages that are applied to both ends of the memory cell MC, that is, the bit line BL and the word line WL, respectively. However, a difference between the voltage levels of both ends of the memory cell MC, that is, the bit line BL and the word line WL, may be the same in the first pre-selection operation and the second pre-selection operation.

Accordingly, the memory cell MC having the abnormal distribution 1 including a threshold voltage having a higher level than the cell determination voltage V_cd may be determined to be turned off even in the second pre-selection operation.

Accordingly, the memory device according to an embodiment of the present disclosure may determine a memory cell having an abnormal distribution to be a failed cell by performing the second pre-selection operation based on the results of the first pre-selection operation.

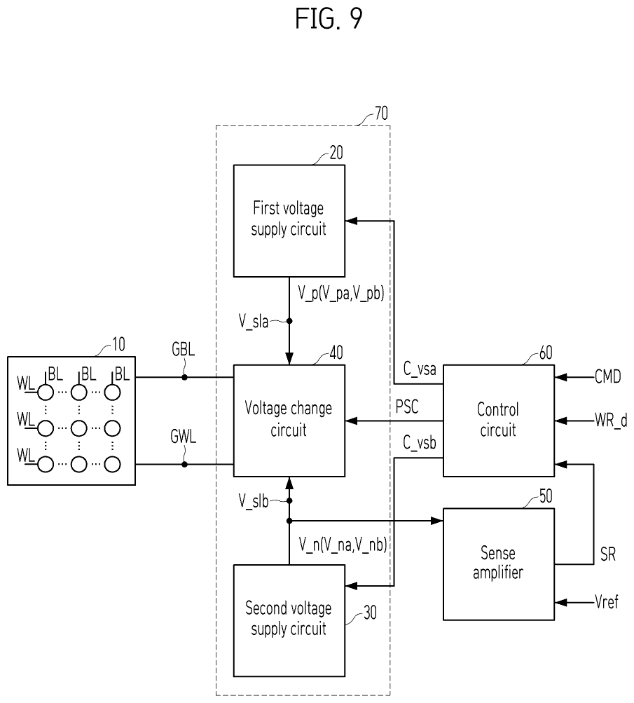

The memory device that operates as described above according to an embodiment of the present disclosure may be constructed as illustrated in FIG. 9.

FIG. 9 is a diagram for describing components of the memory device according to an embodiment of the present disclosure.

Referring to FIG. 9, the memory device according to an embodiment of the present disclosure may include a cell array 10, a first voltage supply circuit 20, a second voltage supply circuit 30, a voltage change circuit 40, a sense amplifier 50, and a control circuit 60.

The cell array 10 may include at least one memory cell MC that is electrically coupled between a bit line BL and a word line WL. In this case, the bit line BL may be electrically coupled to a global bit line GBL. The word line WL may be electrically coupled to a global word line GWL. For example, the bit line BL may be connected to or separated from the global bit line GBL based on an address (not illustrated). Furthermore, the word line WL may be connected to or separated from the global word line GBL based on an address (not illustrated).

The first voltage supply circuit 20 may provide a first voltage V_p to the voltage change circuit 40 through a first voltage line V_sla. In this case, the first voltage V_p may include a first pre-selection operation voltage V_pa and a first write operation voltage V_pb. The first voltage supply circuit 20 may provide one of the first pre-selection operation voltage V_pa and the first write operation voltage V_pb to the voltage change circuit 40 through the first voltage line V_sla as the first voltage V_p based on a first voltage level control signal C_vsa.

The second voltage supply circuit 30 may provide a second voltage V_n to the voltage change circuit 40 through a second voltage line V_slb. In this case, the first voltage V_p may have a higher level than the second voltage V_n. The first voltage V_p may be a positive voltage. The second voltage V_n may be a negative voltage. Furthermore, the second voltage V_n may include a second pre-selection operation voltage V_na and a second write operation voltage V_nb. The second voltage supply circuit 30 may provide one of the second pre-selection operation voltage V_na and the second write operation voltage V_nb to the voltage change circuit 40 through the second voltage line V_slb as the second voltage V_n based on a second voltage level control signal C_vsb.

The voltage change circuit 40 may provide the first voltage V_p to one of the global bit line GBL and the global word line GWL based on a voltage switching control signal PSC, and may provide the second voltage V_n to the other of the global bit line GBL and the global word line GWL. For example, when providing the first voltage V_p to the global bit line GBL based on the voltage switching control signal PSC, the voltage change circuit 40 may provide the second voltage V_n to the global word line GWL. Furthermore, when providing the first voltage V_p to the global word line GWL based on the voltage switching control signal PSC, the voltage change circuit 40 may provide the second voltage V_n to the global bit line GBL.

The sense amplifier 50 may determine whether the memory cell MC has been turned on. For example, the sense amplifier 50 may determine whether the memory cell MC has been turned on by comparing the level of the second voltage line V_slb and the level of a reference voltage Vref after the start of a pre-selection operation, and may output the results of the determination as a sensing result SR. This is described more specifically. After the start of a first pre-selection operation, when the level of the second voltage line V_slb is higher than the level of the reference voltage Vref, the sense amplifier 50 may output the sensing result SR (e.g., a high level) indicating that the memory cell MC has been turned on. After the start of a first pre-selection operation, when the level of the second voltage line V_slb is lower than the level of the reference voltage Vref, the sense amplifier 50 may output the sensing result SR (e.g., a low level) indicating that the memory cell MC has been turned off. Furthermore, after the start of a second pre-selection operation, when the level of the second voltage line V_slb is higher than the level of the reference voltage Vref, the sense amplifier 50 may output the sensing result SR (e.g., a high level) indicating that the memory cell MC has been turned off. After the start of a second pre-selection operation, when the level of the second voltage line V_slb is lower than the level of the reference voltage Vref, the sense amplifier 50 may output the sensing result SR (e.g., a low level) indicating that the memory cell MC has been turned on.

The control circuit 60 may generate the first and second voltage level control signals C_vsa and C_vsb and the voltage switching control signal PSC, based on a command CMD, write data WR_d, and the sensing result SR. Furthermore, the control circuit 60 may provide the first and second voltage level control signals C_vsa and C_vsb to the first and second voltage supply circuits 20 and 30, and may provide the voltage switching control signal PSC to the voltage change circuit 40.

For example, when the command CMD is a write command, the control circuit 60 may provide the first and second voltage supply circuits 20 and 30 with the first voltage level control signal C_vsa that enables the first pre-selection operation voltage V_pa to be output as the first voltage V_p and the second voltage level control signal C_vsb that enables the second pre-selection operation voltage V_na to be output as the second voltage V_n, respectively, so that a first pre-selection operation can be performed. Furthermore, the control circuit 60 may provide the voltage change circuit 40 with the voltage switching control signal PSC that enables the first pre-selection operation voltage V_pa to be provided to the global bit line GBL and that enables the second pre-selection operation voltage V_na to be provided to the global word line GWL. In this case, if the results of the first pre-selection operation, that is, the sensing result SR of the sense amplifier 50, include information indicating that the memory cell MC has been turned on, the control circuit 60 may generate the first and second voltage level control signals C_vsa and C_vsb and the voltage switching control signal PSC so that a write operation according to the write data WR_d is performed.

If the results of the first pre-selection operation, that is, the sensing result SR of the sense amplifier 50, include information indicating that the memory cell MC has been turned off, the control circuit 60 may generate the first and second voltage level control signals C_vsa and C_vsb and the voltage switching control signal PSC so that a second pre-selection operation is performed. In this case, the control circuit 60 may change the voltage switching control signal PSC in the state in which the first and second voltage level control signals C_vsa and C_vsb after the start of the first pre-selection operation have been maintained so that the second pre-selection operation is performed. That is, the control circuit 60 may provide the voltage change circuit 40 with the voltage switching control signal PSC that enables the second pre-selection operation voltage V_na to be provided to the global bit line GBL and that enables the first pre-selection operation voltage V_pa to be provided to the global word line GWL, in the state in which the first and second voltage supply circuits 20 and 30 are provided with the first voltage level control signal C_vsa that enables the first pre-selection operation voltage V_pa to be output as the first voltage V_p and the second voltage level control signal C_vsb that enables the second pre-selection operation voltage V_na to be output as the second voltage V_n, respectively. In this case, if the results of the second pre-selection operation, that is, the sensing result SR of the sense amplifier 50, include information indicating that the memory cell MC has been turned on, the control circuit 60 may generate the first and second voltage level control signals C_vsa and C_vsb and the voltage switching control signal PSC so that a write operation according to the write data WR_d is performed. If the results of the second pre-selection operation, that is, the sensing result SR of the sense amplifier 50, include information indicating that the memory cell MC has been turned off, the control circuit 60 may determine the memory cell MC to be a failed cell.

The control circuit 60 that performs a write operation may generate the first and second voltage level control signals C_vsa and C_vsb that enable the first write operation voltage V_pb and the second write operation voltage V_nb to be provided to the voltage change circuit 40, may provide the first write operation voltage V_pb to one of the global bit line GBL and the global word line GWL based on the write data WR_d, and may generate the voltage switching control signal PSC that enables the second write operation voltage V_nb to be provided to the other of the global bit line GBL and the global word line GWL.

As a result, when a write command is received, the first voltage supply circuit 20, the second voltage supply circuit 30, and the voltage change circuit 40 may perform at least one of a first pre-selection operation, a second pre-selection operation, and a write operation under the control of the control circuit 60. In this case, after the start of the first pre-selection operation, the first voltage supply circuit 20, the second voltage supply circuit 30, and the voltage change circuit 40 may provide the first pre-selection operation voltage V_pa to the global bit line GBL and provide the second pre-selection operation voltage V_na to the global word line WL under the control of the control circuit 60. Furthermore, after the start of the second pre-selection operation, the first voltage supply circuit 20, the second voltage supply circuit 30, and the voltage change circuit 40 may provide the first pre-selection operation voltage V_pa to the global word line GWL and provide the second pre-selection operation voltage V_na to the global bit line GBL under the control of the control circuit 60. Furthermore, after the start of the write operation, the first voltage supply circuit 20, the second voltage supply circuit 30, and the voltage change circuit 40 may provide the first write operation voltage V_pb to one of the global bit line GBL and the global word line GWL and provide the second write operation voltage V_nb to the other of the global bit line GBL and the global word line GWL under the control of the control circuit 60. For example, in a write operation in which the state of the memory cell MC is changed into the set state SET, the first write operation voltage V_pb may be provided to the global bit line GBL, and the second write operation voltage V_nb may be provided to the global word line GWL. Furthermore, in a write operation in which the state of the memory cell MC is changed into the reset state RST, the second write operation voltage V_nb may be provided to the global bit line GBL, and the first write operation voltage V_pb may be provided to the global word line GWL.

Accordingly, the first voltage supply circuit 20, the second voltage supply circuit 30, and the voltage change circuit 40 may be named a voltage supply circuit 70 because the first voltage supply circuit 20, the second voltage supply circuit 30, and the voltage change circuit 40 provide the first and second pre-selection operation voltages V_pa and V_na to the global bit line GBL and the global word line GWL, respectively, or provide the first and second write operation voltages V_pb and V_nb to the global bit line GBL and the global word line GWL, respectively, under the control of the control circuit 60.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A method for operating a memory device, the method comprising:
receiving a first write command;
performing a first pre-selection operation to determine whether a first memory cell is capable of being turned on;
performing a second pre-selection operation to determine whether the first memory cell is capable of being turned on if the first pre-selection operation did not cause the first memory cell to be turned on; and
determining the first memory cell to be a failed cell if the second pre-selection operation did not cause the first memory cell to be turned on.

2. The method of claim 1, further comprising:
performing a write operation on the first memory cell in response to the first write command if the second pre-selection operation causes the first memory cell to turn on,
wherein a first current flow of the first memory cell is in a first direction if the first memory cell is turned on by the first pre-selection operation, and a second current flow of the first memory cell is in a second direction if the first memory cell is turned on by the second pre-selection operation, the first and second directions being different directions.

3. The method of claim 2, wherein:
the first current flow in the first direction is from a bit line to a word line through the first memory cell, and
the second current flow in the second direction is from the word line to the bit line through the first memory cell.

4. The method of claim 3, wherein a difference between levels of voltages applied to first and second ends of the first memory cell in each of the first and second pre-selection operations is smaller than a difference between the levels of the voltages applied to first and second ends of the first memory cell after a start of a write operation.

5. The method of claim 1, further comprising:
receiving a second write command;
performing a third pre-selection operation to determine whether a second memory cell is capable of being turned on; and
performing a write operation on the second memory cell in response to the second write command if the second memory cell is determined to be turned on.

6. The method of claim 1, further comprising:
receiving a third write command;
performing a fourth pre-selection operation to determine whether a third memory cell is capable of being turned on;
performing a fifth pre-selection operation if the fourth pre-selection operation did not cause the third memory cell to turn on; and
performing a write operation on the third memory cell if the third memory cell is turned on by the fifth pre-selection operation.

7. The method of claim 6, wherein:
the fourth pre-selection operation is an operation for causing a current flow from a bit line to a word line through the third memory cell, and
the fifth pre-selection operation is an operation for causing a current flow from the word line to the bit line through the third memory cell.

8. A memory device, comprising:
a cell array comprising at least one memory cell that is electrically coupled between a bit line and a word line, the bit line being electrically coupled to a global bit line, the word line being electrically coupled to a global word line;
a control circuit configured to control one or more of a first pre-selection operation, a second pre-selection operation, and a write operation, in response to a write command received;
a voltage supply circuit configured to provide a first pre-selection operation voltage to the global bit line and a second pre-selection operation voltage to the global word line after a start of the first pre-selection operation; and
a sense amplifier configured to provide the control circuit with information indicating whether the memory cell has been turned on in response to at least one of the first or the second pre-selection operation.

9. The memory device of claim 8, wherein the first pre-selection operation involves current flowing in a first direction and the second pre-selection operation involves current flowing in a second direction when the memory cell is turned on.

10. The memory device of claim 9, wherein
the first pre-selection operation causes a current flow from the bit line to the word line through the memory cell that has been turned on, and
the second pre-selection operation causes a current flow from the word line to the bit line through the memory cell that has been turned on.

11. The memory device of claim 10, wherein a difference between levels of voltages applied across the memory cell in each of the first and second pre-selection operations is smaller than a difference between the levels of the voltages applied across the memory cell during the write operation.

12. The memory device of claim 9, wherein when the write command is received, the control circuit controls the write operation to be performed if the memory cell has been turned on in response to the first pre-selection operation.

13. The memory device of claim 9, wherein when the write command is received, the control circuit controls the second pre-selection operation to be performed if the memory cell has not been turned on in response to the first pre-selection operation.

14. The memory device of claim 13, wherein the control circuit is configured to control the write operation to be performed if the memory cell has been turned on in response to the second pre-selection operation, and classify the memory cell to be a failed cell if the memory cell has not been turned on in response to the second pre-selection operation.

15. The memory device of claim 9, wherein the voltage supply circuit provides the first pre-selection operation voltage to the global word line and the second pre-selection operation voltage to the global bit line after a start of the second pre-selection operation.

16. The memory device of claim 15, wherein the voltage supply circuit provides the first and second pre-selection operation voltages to the global bit line and the global word line, respectively, so that a difference between voltage levels of the global bit line and the global word line is smaller after a start of the first and second pre-selection operations than after a start of the write operation.

17. The memory device of claim 16, wherein the voltage supply circuit comprises:
a first voltage supply circuit configured to output the first pre-selection operation voltage after the start of the first and second pre-selection operations and configured to output the first write operation voltage after the start of the write operation;
a second voltage supply circuit configured to output the second pre-selection operation voltage after the start of the first and second pre-selection operations and configured to output the second write operation voltage after the start of the write operation; and
a voltage change circuit configured to provide the output of the first voltage supply circuit to the global bit line and to provide the output of the second voltage supply circuit to the global word line after the start of the first pre-selection operation and configured to provide the output of the first voltage supply circuit to the global word line and to provide the output of the second voltage supply circuit to the global bit line after the start of the second pre-selection operation.

18. A method for operating a non-volatile memory device, the method comprising:
receiving a write command for a memory cell;
performing a first pre-selection operation on the memory cell;
performing a second pre-selection operation on the memory cell if the memory cell does not exhibit a conductive state in response to the first pre-selection operation;
performing the write operation on the memory cell if the memory cell exhibits a conductive state in response to at least one of the first or second pre-selection operations; and
classifying the memory cell as a failed cell if the memory cell does not exhibit a conductive state in response to the first and second pre-selection operations.

19. The method of claim 18, wherein the first pre-selection operation involves applying a first voltage across the memory cell to cause a current flow from a bit line to a word line through the memory cell, and the second pre-selection operation involves applying a second voltage across the memory cell to cause a current flow from the word line to the bit line through the memory cell.

20. The method of claim 19, wherein a voltage difference applied across the memory cell during each of the first and second pre-selection operations is less than a voltage difference applied across the memory cell during the write operation.
